(19) United States
(12) Patent Application Publication
(10) Pub. No.: US 2018/0061484 A1
(43) Pub. Date: Mar. 1, 2018

(54) Systems and Methods for Memory Refresh Timing

(71) Applicant: Apple Inc., Cupertino, CA (US)

(72) Inventor: Sukalpa Biswas, Fremont, CA (US)

(21) Appl. No.: 15/451,548

(22) Filed: Mar. 7, 2017

Related U.S. Application Data
(60) Provisional application No. 62/380,530, filed on Aug. 29, 2016.

(51) Int. Cl. G11C 11/406; G06F 3/06

(52) U.S. Cl. CPC G11C 11/40615; G06F 3/0673; G06F 3/0659; G06F 3/0619

(57) ABSTRACT

In an embodiment, an integrated circuit (IC) and a memory device are configured to operate in a “normal” mode and a “self refresh” mode. The IC may generate refresh commands according to a refresh interval during normal mode. The memory device may be responsible for refresh during the self refresh mode. The IC may ensure that the amount of time that has expired in the current refresh interval prior to entering self refresh mode is retained, so that a remaining amount of time may expire after self refresh mode is exited prior to generating the initial refresh command after exiting self refresh mode. Similarly, the memory device may retain the amount of time that has expired in the current self refresh interval prior to exiting self refresh, so that a remaining amount of time may expire after self refresh mode is entered again prior to performing an initial self refresh.

This application claims benefit of priority to U.S. Provisional Application No. 62/380,530, filed on Aug. 29, 2016, which is hereby incorporated by reference in its entirety. To the extent that anything in the above application conflicts with material expressly set forth herein, the material expressly set forth herein controls.

### BACKGROUND

### Technical Field

Embodiments described herein are related to refresh timing for memory systems.

### Description of the Related Art

Certain types of memory devices require refresh to ensure that the data stored in the memory remains correctly stored there (i.e. without incurring unexpected change while stored). For example, dynamic random access memories (DRAMs) generally include a capacitor on which charge is deposited or removed to store a logical one or logical zero. Over time, the charge may have a tendency to leak away from the capacitor, which leads to loss of data. To prevent this, each memory location in the DRAM is required to be refreshed (read and then written with the same data) at least once prior to the expiration of an interval during which correct storage of the data is guaranteed by the manufacturer of the DRAM. Dividing the period by the total number of memory locations in the DRAM results in a refresh interval. If a refresh of a memory location is performed once each refresh interval, and all memory locations are refreshed before a given memory location is refreshed a second time, then data loss can be avoided.

The refresh interval specifies the minimum frequency at which the refreshes can occur in a memory, but it is acceptable to refresh more frequently than the refresh interval. On the other hand, refreshes consume power in the same manner that other read and write operations do, so refreshing more often than required to maintain data storage consumes power unnecessarily. For power-sensitive devices such as various battery-powered devices, consuming power unnecessarily is undesirable. Additionally, various power-saving modes that are often used in such power-sensitive devices, and frequent switching between the modes, makes tracking refreshes across such modes more problematic. For example, on entry into a mode in which the memory is responsible for refresh (“self refresh” mode), the memory does not have information on when the next refresh is due. Accordingly, to ensure data integrity, the memory performs a precautionary refresh on entry to self refresh mode. Similarly, on entry to a mode in which the circuitry interfacing to the memory is responsible for refresh, the circuitry does not have information on when the next self refresh is due. Accordingly, to ensure data integrity, the circuitry performs a precautionary refresh on entry to such a mode.

### SUMMARY

In an embodiment, an integrated circuit (IC) and a memory device are configured to operate in at least one “normal” mode and at least one self refresh mode. The normal mode (or “functional” mode or “operational” mode) may be a mode in which the IC may read and write locations in the memory device. The IC may also generate refresh commands according to a refresh interval during normal mode. The self refresh mode may be a mode in which the interface between the IC and memory device is inactive (and the IC may even be powered down). The memory device may internally be responsible for refresh during the self refresh mode. The IC may ensure that the amount of time that has expired in the current refresh interval prior to entering self refresh mode is retained, so that a remaining amount of time may expire after self refresh mode is exited prior to generating the initial refresh command after exiting self refresh mode. Similarly, the memory device may retain the amount of time that has expired in the current self refresh interval prior to exiting self refresh, so that a remaining amount of time may expire after self refresh mode is entered again prior to performing an initial self refresh.

### BRIEF DESCRIPTION OF THE DRAWINGS

The following detailed description makes reference to the accompanying drawings, which are now briefly described.

FIG. 1 is a block diagram of one embodiment of an integrated circuit coupled to one or more DRAMs.

FIG. 2 is a timing diagram illustrating refresh timing for an embodiment.

FIG. 3 is a flowchart illustrating operation of one embodiment of the integrated circuit and the DRAM for self-refresh mode.

FIG. 4 is a timing diagram illustrating operation of one embodiment of the integrated circuit and the DRAM to exit self-refresh mode and operate in functional mode.

FIG. 5 is a block diagram of one embodiment of a system.

FIG. 6 is a block diagram of one embodiment of a computer accessible storage medium.

While embodiments described in this disclosure may be susceptible to various modifications and alternative forms, specific embodiments thereof are shown by way of example in the drawings and will herein be described in detail. It should be understood, however, that the drawings and detailed description thereto are not intended to limit the embodiments to the particular form disclosed, but on the contrary, the intention is to cover all modifications, equivalents and alternatives falling within the spirit and scope of the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include”, “including”, and “includes” mean including, but not limited to.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “clock circuit configured to generate an output clock signal” is intended to cover, for example, a circuit that performs this function during operation, even if the circuit in question is not currently being used (e.g., power is not connected to it). Thus, an entity described or recited as “configured to” perform some task refers to something physical, such as a device, circuit, memory storing program instructions executable to implement the task, etc. This phrase is not used herein to refer to something intangible. In general, the circuitry that forms the structure corresponding to “configured to” may include hardware circuits. The hardware circuits may include any combination of combinatorial logic circuitry, clocked storage devices such as flops, registers, latches, etc., finite state machines, memory such as static random access memory or embedded dynamic random access memory, custom designed circuitry, analog circuitry, programmable logic arrays, etc. Similarly, various units/circuits/components may be described as performing a task or tasks, for convenience in the description. Such descriptions should be interpreted as including the phrase “configured to.”

The term “configured to” is not intended to mean “configurable to.” An unprogrammed FPGA, for example, would not be considered to be “configured to” perform some specific function, although it may be “configurable to” perform that function. After appropriate programming, the FPGA may then be configured to perform that function.

Reciting in the appended claims a unit/circuit/component or other structure that is configured to perform one or more tasks is expressly intended not to invoke 35 U.S.C. § 112(f) interpretation for that claim element. Accordingly, none of the claims in this application as filed are intended to be interpreted as having means-plus-function elements. Should Applicant wish to invoke Section 112(f) during prosecution, it will recite claim elements using the “means for” [performing a function] construct.

In an embodiment, hardware circuits in accordance with this disclosure may be implemented by coding the description of the circuit in a hardware description language (HDL) such as Verilog or VHDL. The HDL description may be synthesized against a library of cells designed for a given integrated circuit fabrication technology, and may be modified for timing, power, and other reasons to result in a final design database that may be transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and may further include other circuit elements (e.g. passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA.

As used herein, the term “based on” or “dependent on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

This specification includes references to various embodiments, to indicate that the present disclosure is not intended to refer to one particular implementation, but rather a range of embodiments that fall within the spirit of the present disclosure, including the appended claims. Particular features, structures, or characteristics may be combined in any suitable manner consistent with this disclosure.

### DETAILED DESCRIPTION OF EMBODIMENTS

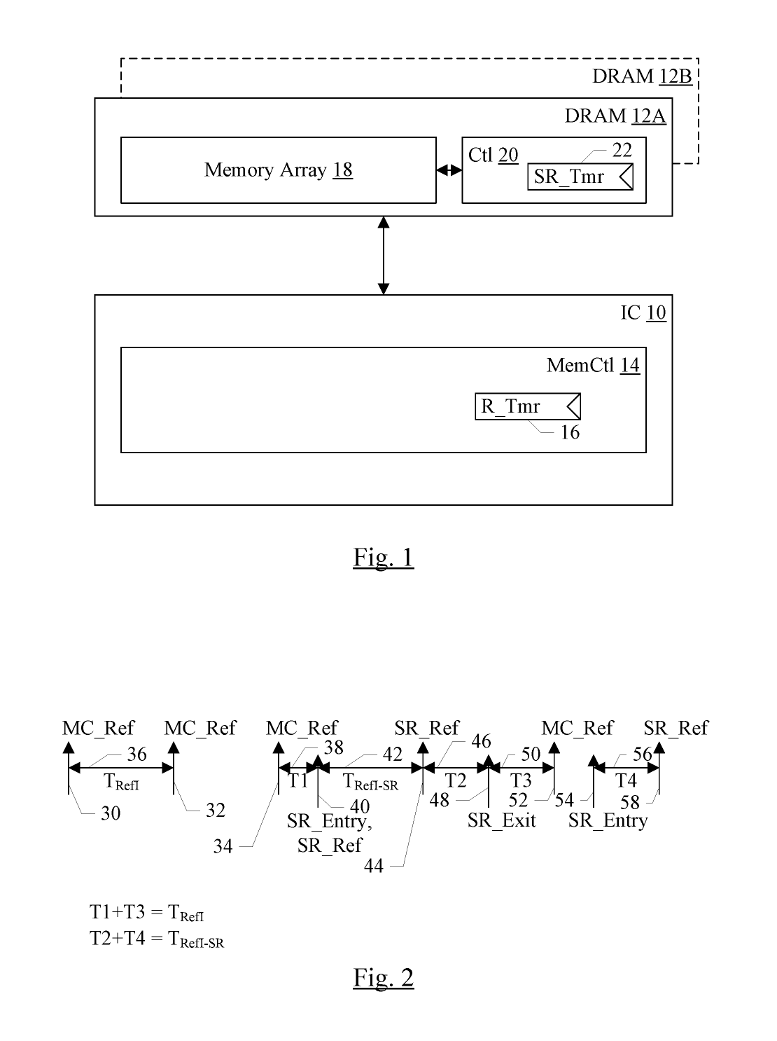

Turning now to FIG. 1, a block diagram of one embodiment of an IC 10 coupled to one or more DRAMs such as DRAMs 12A-12B. The IC 10 may include memory control (MemCtl) circuit 14 (more briefly “memory controller”), which may include a refresh timer (R_Tmr) register 16. The DRAM 12A may include a memory array 18 that stores the data in the DRAM 12A and a control circuit 20 coupled to the memory array 18. The control circuit 20 may include a self refresh timer (SR_Tmr) register 22. DRAM 12B is optional, and there may be more DRAMs similar to DRAMs 12A-12B in other embodiments. Each DRAM may have components similar to the components illustrated for DRAM 12A in FIG. 1.

The memory controller 14 may be configured to interface to the DRAMs 12A-12B over an external interface between the IC 10 and the DRAMs 12A-12B. For example, the external interface may be an industry standard interface implemented by a variety of DRAM device vendors. The memory controller 14 may be configured to transmit read and write commands to the DRAMs 12A-12B, and to transmit and receive data, over the interface. Additionally, the memory controller 14 may be configured to transmit refresh commands over the interface to cause refreshes in the DRAMs 12A-12B. In another embodiment, the DRAMs 12A-12B may be integrated into the IC 10 (e.g. using embedded DRAM technology), and self-refresh may still be in the DRAM in various power saving modes. A similar mechanism to that described below may be implemented in the integrated case as well.

The memory controller 14 may be configured to track a refresh interval using the refresh timer register 16. For example, the refresh timer register 16 may be loaded with a value representing the refresh interval, and the memory controller 14 may decrement the value to zero. When zero is reached, the memory controller 14 may be configured to generate a refresh command and reload the refresh timer register 16 with the value. The value may be based on the clock that is supplied to the memory controller 14 to clock various digital circuitry therein, or may be based on a clock that is supplied separately and that is a constant frequency during operation (where the memory controller 14 may be clocked at different frequencies depending on the power state of the IC 10). Alternatively, the refresh timer register 16 may be reset to zero and incremented to reach the value representing the refresh interval.

The memory controller 14 may track the refresh interval during normal mode, when the interface to the DRAMs 12A-12B may be active and the memory controller 14 may be able to transmit read/write commands to the DRAMs 12A-12B. At certain points, power management circuitry in the IC 10 or in a separate IC (not shown) may be determine that the IC 10 is to enter a low power mode (e.g. clock gated, power gated, etc.). The IC 10 may have various subsections (clock domains/power domains) for which power management decisions may be made independently. If the domain including the memory controller 14 is to be clock gated and/or power gated, or if the IC 10 is entering a mode in which external memory accesses to the DRAMs 12A-12B are not permitted, the memory controller 14 may transmit a command to the DRAMs 12A-12B to enter self refresh mode. Additionally, in response to self refresh mode entry, the memory controller 14 may be configured to freeze the value of the refresh timer register 16. For example, if the memory controller 14 is to be powered down, the refresh timer register 16 may be placed on retention voltage to ensure the power is maintained. The memory controller 14 may ensure that the value is not incremented or decremented during self-refresh mode. Accordingly, when self refresh mode is exited and the refresh timer updates restart, the correct amount of time during normal mode may pass prior to the next refresh even if the interval is interrupted by time in self refresh mode.

Similarly, the control circuit 20 may track the self refresh interval in the self refresh timer register 22 (e.g. load value and decrement or clear value and increment as discussed above for the refresh timer register 16). The control circuit 20 may freeze the value in the self refresh timer register 22 during normal mode. Accordingly, the amount of time between self refreshes may be correctly determined even if the interval is interrupted by time in normal mode.

Viewed in another way, the memory controller 14 may be configured to trigger refreshes over a refresh interval measured during normal mode (and excluding time in self refresh mode) while the control circuit 20 may be configured to trigger self refreshes over a self refresh interval measured during self refresh mode (and excluding time in normal mode). Thus, the overall self refresh frequency may be at least the required frequency and data may be protected. Additionally, excessive refreshing may be minimized. Accordingly, power that would be lost performing excessive refreshes may be conserved.

The refresh command from the memory controller 14 to the DRAMs 12A-12B may have any format. It may include at least the command to perform the refresh. Optionally, the refresh command may indicate the memory location to be refreshed (and optionally a bank, in banked versions of DRAMs 12A-12B). Banked versions may also support an “all banks” refresh command that concurrently refreshes each bank. Alternatively, the DRAMs 12A-12B may track which memory locations to refresh (and may increment the refresh address after each refresh/self refresh is complete) and thus the refreshes may march through consecutive memory addresses over time. In an embodiment, the “all banks” refresh command may be used for both refresh commands issued by the IC 10 and the self refresh commands generated internally by the DRAMs 12A-12B. Other embodiments may use single bank refresh commands or a mix of refresh command types.

It is noted that the refresh interval tracked by the refresh timer register 16 and the self refresh interval tracked by the self refresh timer register 22 may refer to approximately the same amount of real time, within the granularity of the respective clock frequencies used to update the registers 16 and 22. However, the values tracked may differ because the frequencies of the clocks used by the DRAMs 12A-12B and the IC 10 to manage the updates may differ.

In some embodiments, the IC 10 may include additional circuitry with the memory controller 14. For example, the IC 10 may be a system on a chip (SOC) including one or more processors serving as central processing units (CPUs) and optionally included various other peripheral devices and/or interface circuits. Any functionality may be integrated with the memory controller 14 on the IC 10 in various embodiments.

The DRAMs 12A-12B may be packaged in any desired fashion. For example, the DRAMs 12A-12B may be packaged in a chip on chip or package on package technology with the IC 10. Alternatively, a multichip module may be used, or the IC 10 may be packaged separately from the DRAMs 12A-12B (which may be on a dual inline memory module (DIMM), single inline memory module (SIMM), discrete chips on a board with the IC 10, etc.).

FIG. 2 is a timing diagram illustrating operation of one embodiment of the IC 10 and the DRAMs 12A-12B. Time increases from left to right in FIG. 2. On the left in FIG. 2, the IC 10 and DRAMs 12A-12B are operating in normal mode and thus the memory controller 14 is responsible for transmitting refresh commands. Three refresh commands are illustrated in FIG. 2 (arrows 30, 32, and 34) separated by a period of time specified as T_{RefI} (time for refresh interval), illustrated as arrow 36. Subsequent to the refresh command at arrow 34, a time period T1 (less than T_{RefI}) expires (arrow 38) and the self refresh mode is entered (arrow 40). In this example, the entry into self refresh at arrow 40 may be the initial entry into self refresh mode since power up. Accordingly, a self refresh is generated by the control circuit 20 (SR_Ref) at arrow 40. A time T_{RefI-SR} (time for refresh interval-self refresh, arrow 42) another self refresh is generated (arrow 44). A time T2 (less than T_{RefI-SR}, arrow 46), self refresh exits (arrow 48). A time T3 after self refresh exit (arrow 50), the memory controller 14 issues a refresh command (arrow 52). As illustrated by the equation at the bottom of FIG. 2, T1+T3 is equal to T_{RefI}. In an embodiment, the time T1+T3 is approximately equal to T_{RefI}, because there may be some correction to account for potential loss of a clock tick when switching from normal mode to self refresh mode or vice versa. Subsequently, self refresh mode is entered again (arrow 54), and a time T4 later (arrow 56), the control circuit 58 generates another self refresh (arrow 58). As illustrated in the equation at the bottom of FIG. 2, the time T2+T4 is equal (or may be approximately equal) to T_{RefI-SR}.

While in some cases in FIG. 2, a refresh and a self refresh may occur in temporal proximity that is less than T_{RefI}/T_{RefI-SR} (e.g. at arrows 32 and 40, or 48 and 52), each refresh in normal mode may be separated from the previous refresh in normal mode by approximately T_{RefI} (measured in normal mode only). Similarly, each self refresh in self refresh mode may be separated from the previous self refresh by T_{RefI-SR}. Over a complete cycle of refreshes (top to bottom of the memory array 18), excess refreshes to due to mode changes may be minimized or even eliminated. Additionally, precautionary refreshes at the entry to a given mode (normal or self refresh) may be eliminated.

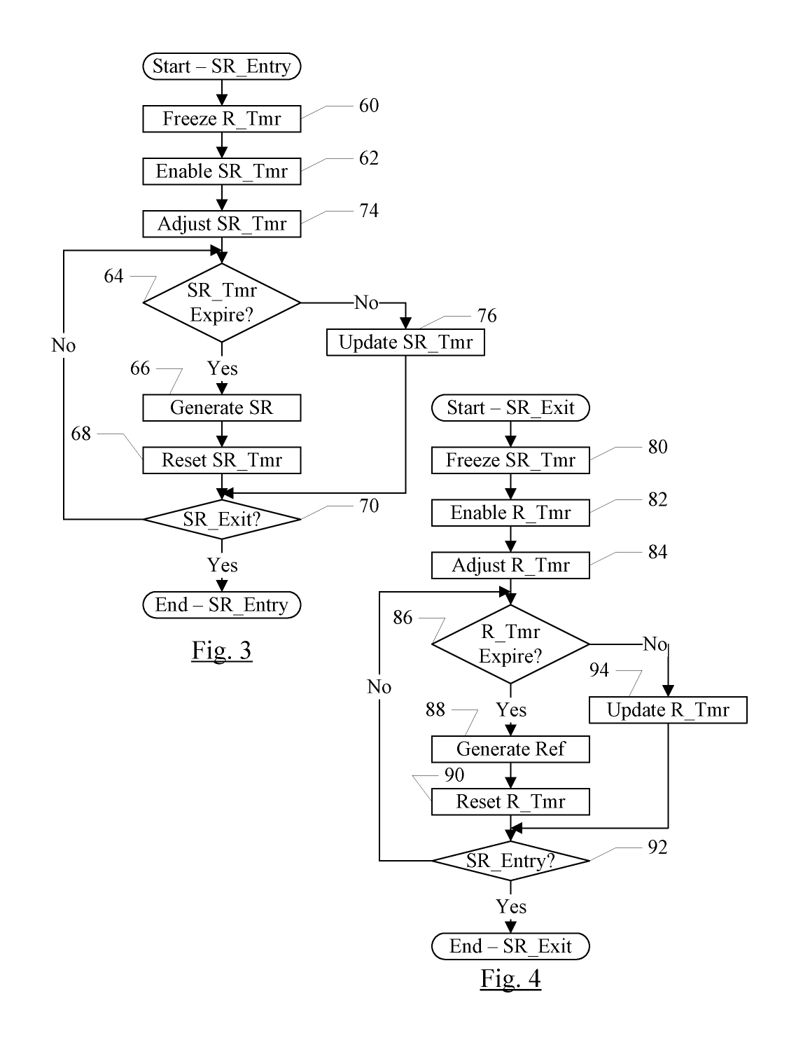

FIG. 3 is a flowchart illustrating operation of one embodiment of the IC 10 and the DRAMs 12A-12B upon entry into self refresh mode and up until exit from self refresh mode. While the blocks are shown in a particular order for ease of understanding, any order may be used. Blocks may be performed in parallel in combinatorial logic in the IC 10 and/or DRAMs 12A-12B. Blocks, combinations of blocks, and/or the flowchart as a whole may be pipelined over multiple clock cycles. The IC 10 and/or the DRAMs 12A-12B may be configured to implement the operation shown in FIG. 3. Each of the DRAMs 12A-12B may include an instance of the control circuit 20 to independently implement the operation shown in FIG. 3 and assigned to the DRAMs 12A-12B, and may not have the same operation on a given clock cycle.

Since self refresh mode is being entered, the IC 10 (and more particularly, the memory controller 14) may freeze the refresh timer register 16, holding the value steady while the apparatus is in self refresh mode (block 60). The DRAMs 12A-12B (and more particularly the control circuit 20) may enable the self refresh timer register 22 (block 62). Additionally, in some embodiments, the DRAMs 12A-12B/control circuit 20 may be configured to adjust the self refresh timer register 22 (block 74). The adjustment may be performed to: compensate for quantization error in the counting of clock pulses at a given frequency; account for time lost during the mode change (e.g. about 200 nanoseconds in one embodiment); and/or account for any other sources of error in a given implementation. For example, the adjustment may be to increment the self refresh timer register 22 (e.g. incrementing by one tick).

If the self refresh timer expires (decision block 64, “yes” leg), the DRAMs 12A-12B/control circuit 20 may generate a self refresh (block 66) and reset the self refresh timer register 22 (block 68). If a self refresh exit is detected (e.g. a command from the IC 10 is received indicating self-refresh exit—decision block 70, “yes” leg), then the flow chart may exit to normal mode as shown in FIG. 4 and described below. If the self refresh exit is not detected (decision block 70, “no” leg), operation may continue in self refresh mode.

If the self refresh timer does not expire (decision block 64, “no” leg), the DRAMs 12A-12B/control circuit 20 may update the self refresh timer register 22 (block 76). The update may be conditional on another tick of the clock that is used to update the self refresh timer register 22 being detected. For example, ticks may occur on the order of every 500 nanoseconds (nsec) or 1 microsecond. In other embodiments, higher or lower frequencies may be used. A check for self refresh exit may be performed (decision block 70) as discussed above.

FIG. 4 is a flowchart illustrating operation of one embodiment of the IC 10 and the DRAMs 12A-12B upon exit from self refresh mode/entry into normal mode, and up until entry to self refresh mode. While the blocks are shown in a particular order for ease of understanding, any order may be used. Blocks may be performed in parallel in combinatorial logic in the IC 10 and/or DRAMs 12A-12B. Blocks, combinations of blocks, and/or the flowchart as a whole may be pipelined over multiple clock cycles. The IC 10 and/or the DRAMs 12A-12B may be configured to implement the operation shown in FIG. 4. Each of the DRAMs 12A-12B may include and the control circuit 20 to independently implement the operation shown in FIG. 4 and assigned to the DRAMs 12A-12B, and may not have the same operation on a given clock cycle.

Since self refresh mode is being exited, the DRAMs 12A-12B/control circuit 20 may freeze the self refresh timer register 22, holding the value steady while the apparatus is in normal mode (block 80). The IC 10/memory controller 14 may enable the refresh timer register 16 (block 82). Additionally, in some embodiments, the IC 10/memory controller 14 may be configured to adjust the refresh timer register 16 (block 84). The adjustment may be performed to: compensate for quantization error in the counting of clock pulses at a given frequency; account for time lost during the mode change (e.g. about 200 nanoseconds in one embodiment); and/or account for any other sources of error in a given implementation. For example, the adjustment may be to increment the refresh timer register 16 by 2 (e.g. incrementing by two ticks).

If the refresh timer expires (decision block 86, “yes” leg), the IC 10/memory controller 14 may generate a refresh command to the memory controller 14 (block 88) and reset the refresh timer register 16 (block 90). If a self refresh entry is detected (e.g. the power management circuitry controller the IC 10 indicates that self refresh mode is desired, and thus the IC 10 transmits a self refresh command to the DRAMs 12A-12B—decision block 92, “yes” leg), then the flow chart may exit to self refresh entry as shown in FIG. 3 and described above. If the self refresh entry is not detected (decision block 92, “no” leg), operation may continue in normal mode.

If the refresh timer does not expire (decision block 86, “no” leg), the IC 10/memory controller 14 may update the self refresh timer register 16 (block 94). The update may be conditional on detecting another tick (e.g. rising edge) of the clock that is used to update the refresh timer register 16. For example, ticks may occur on the order of every 41.67 nanoseconds (nsec) in an embodiment. In other embodiments, higher or lower frequencies may be used. A check for self refresh exit may be performed (decision block 86) as discussed above.

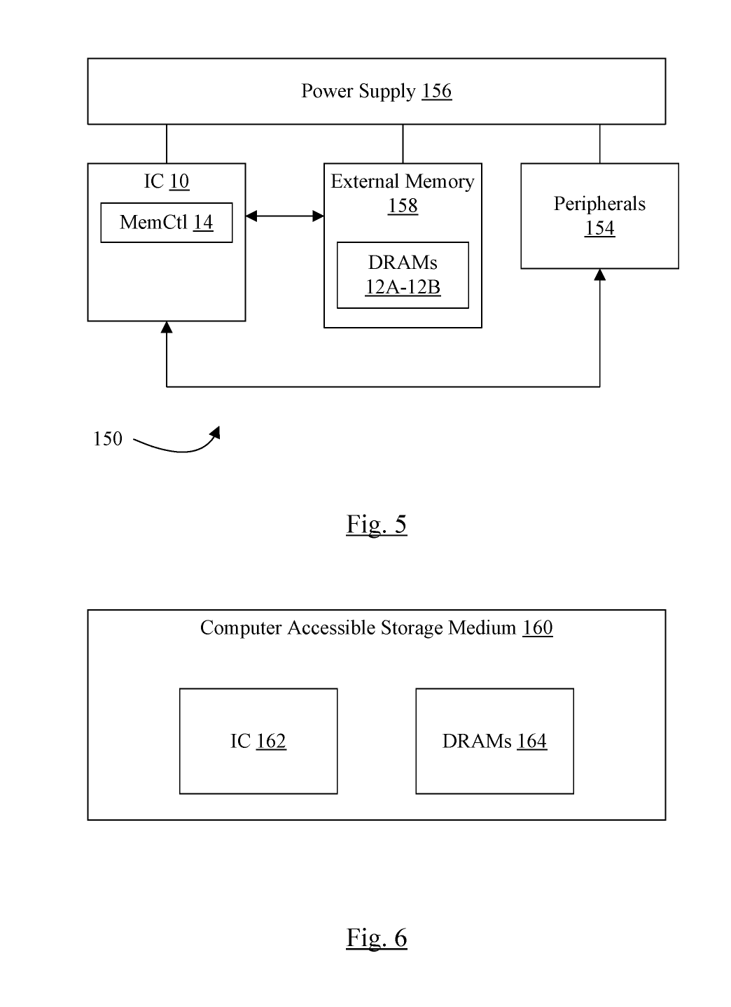

FIG. 5 is a block diagram of one embodiment of a system 150. In the illustrated embodiment, the system 150 includes at least one instance of an integrated circuit (IC) 10 (including the memory controller 14) coupled to one or more peripherals 154 and an external memory 158 (including the DRAMs 12A-12B). A power supply 156 is provided which supplies the supply voltages to the IC 10 as well as one or more supply voltages to the memory 158 and/or the peripherals 154.

The peripherals 154 may include any desired circuitry, depending on the type of system 150. For example, in one embodiment, the system 150 may be a computing device (e.g., personal computer, laptop computer, etc.), a mobile device (e.g., personal digital assistant (PDA), smart phone, tablet, etc.). In various embodiments of the system 150, the peripherals 154 may include devices for various types of wireless communication, such as wifi, Bluetooth, cellular, global positioning system, etc. The peripherals 154 may also include additional storage, including RAM storage, solid state storage, or disk storage. The peripherals 154 may include user interface devices such as a display screen, including touch display screens or multitouch display screens, keyboard or other input devices, microphones, speakers, etc. In other embodiments, the system 150 may be any type of computing system (e.g. desktop personal computer, laptop, workstation, net top etc.).

The external memory 158 may include any type of memory. For example, the external memory 158 may be SRAM, dynamic RAM (DRAM) such as synchronous DRAM (SDRAM), double data rate (DDR, DDR2, DDR3, etc.) SDRAM, RAMBUS DRAM, low power versions of the DDR DRAM (e.g. LPDDR, mDDR, etc.), etc. The DRAMs 12A-12B may be any type of such DRAM as listed above. The external memory 158 may include one or more memory modules to which the memory devices are mounted, such as single inline memory modules (SIMMs), dual inline memory modules (DIMMs), etc. Alternatively, the external memory 158 may include one or more memory devices that are mounted on the IC 10 in a chip-on-chip or package-on-package implementation.

FIG. 6 is a block diagram of one embodiment of a computer accessible storage medium 160 storing an electronic description of the IC 10 (reference numeral 162) is shown. More particularly, the description may include the memory controller 14. The description may further include a description 164 of the DRAMs 12A-12B, including the control circuit 20. Generally speaking, a computer accessible storage medium may include any storage media accessible by a computer during use to provide instructions and/or data to the computer. For example, a computer accessible storage medium may include storage media such as magnetic or optical media, e.g., disk (fixed or removable), tape, CD-ROM, DVD-ROM, CD-R, CD-RW, DVD-R, DVD-RW, or Blu-Ray. Storage media may further include volatile or non-volatile memory media such as RAM (e.g. synchronous dynamic RAM (SDRAM), Rambus DRAM (RDRAM), static RAM (SRAM), etc.), ROM, or Flash memory. The storage media may be physically included within the computer to which the storage media provides instructions/data. Alternatively, the storage media may be connected to the computer. For example, the storage media may be connected to the computer over a network or wireless link, such as network attached storage. The storage media may be connected through a peripheral interface such as the Universal Serial Bus (USB). Generally, the computer accessible storage medium 160 may store data in a non-transitory manner, where non-transitory in this context may refer to not transmitting the instructions/data on a signal. For example, non-transitory storage may be volatile (and may lose the stored instructions/data in response to a power down) or non-volatile.

Generally, the electronic descriptions 162 and 164 stored on the computer accessible storage medium 160 may be a database which can be read by a program and used, directly or indirectly, to fabricate the hardware comprising the IC 10/DRAMs 12A-12B. For example, the description may be a behavioral-level description or register-transfer level (RTL) description of the hardware functionality in a high level design language (HDL) such as Verilog or VHDL. The description may be read by a synthesis tool which may synthesize the description to produce a netlist comprising a list of gates from a synthesis library. The netlist comprises a set of gates which also represent the functionality of the hardware comprising the IC 10/DRAMs 12A-12B. The netlist may then be placed and routed to produce a data set describing geometric shapes to be applied to masks. The masks may then be used in various semiconductor fabrication steps to produce a semiconductor circuit or circuits corresponding to the IC 10/DRAMs 12A-12B. Alternatively, the descriptions 162-164 on the computer accessible storage medium 300 may be the netlist (with or without the synthesis library) or the data set, as desired.

While the computer accessible storage medium 160 stores a description 162 of the IC 10 and a description 164 of the DRAMs 12A-12B, other embodiments may store a description 162 of any portion of the IC 10 and/or a description 164 of any portion of the DRAMs 12A-12B, as desired (e.g. the memory controller 14 and/or the control circuit 20 as mentioned above).

Numerous variations and modifications will become apparent to those skilled in the art once the above disclosure is fully appreciated. It is intended that the following claims be interpreted to embrace all such variations and modifications.

What is claimed is:

1. An apparatus comprising:
a memory device; and
a memory controller coupled to the memory device wherein:
the memory controller is configured to generate refresh commands for the memory device dependent on a first refresh timer maintained by the memory controller;
the memory controller is configured to ensure that a first amount of time expiring in a refresh interval indicated by the first refresh timer at entry to self refresh mode in the memory device is maintained;
the memory controller is configured to trigger a next refresh command after exit from self refresh mode and after a second amount of time from the exit, wherein a sum of the first amount of time and the second amount of time is approximately the refresh interval;
the memory device is configured to generate self refresh commands for the memory device during self refresh mode dependent on a second refresh timer maintained by the memory device;
the memory device is configured to ensure that a third amount of time expiring in a second refresh interval indicated by the second refresh timer at exit from the self refresh mode in the memory device is maintained; and
the memory device is configured to trigger a next self refresh command after entry into self refresh mode and after a fourth amount of time from the entry, wherein a sum of the third amount of time and the fourth amount of time is approximately the second refresh interval.

2. The apparatus as recited in claim 1, wherein the memory controller is configured to hold the first refresh timer at a first value indicating the first amount of time at entry to self refresh mode.

3. The apparatus as recited in claim 2, wherein the memory controller is configured to adjust the first value in response to the exit from self refresh mode by a first adjustment amount.

4. The apparatus as recited in claim 3, wherein the first adjustment amount accounts for time lost during exit from self refresh mode.

5. The apparatus as recited in claim 3, wherein the first adjustment amount accounts for quantization error in counting pulses of a clock signal that controls the first refresh timer.

6. The apparatus as recited in claim 3, wherein the first adjustment amount accounts for sources of error in measuring the refresh interval.

7. The apparatus as recited in claim 2, wherein the first refresh timer is on retention if the memory controller is powered down.

8. The apparatus as recited in claim 1, wherein the next refresh command after the exit from self refresh mode is an initial refresh command after the exit.

9. The apparatus as recited in claim 1, wherein the memory device is configured to hold the second refresh timer at a second value indicating the second amount of time at exit from self refresh mode.

10. The apparatus as recited in claim 9, wherein the memory device is configured to adjust the second value in response to entry to the self refresh mode by a second adjustment amount.

11. The apparatus as recited in claim 10, wherein the second adjustment amount accounts for time lost during entry to self refresh mode.

12. The apparatus as recited in claim 10, wherein the second adjustment amount accounts for quantization error in counting pulses of a clock signal that controls the second refresh timer.

13. The apparatus as recited in claim 10, wherein the second adjustment amount accounts for sources of error in measuring the refresh interval.

14. The apparatus as recited in claim 1, wherein the next self refresh command after the entry to self refresh mode is an initial self refresh command after the entry.

15. An integrated circuit comprising:
a memory device;
a first refresh timer; and
a memory controller configured to interface to the memory device, wherein the memory controller is configured to generate refresh commands for the memory device dependent on the first refresh timer maintained by the memory controller, and wherein the memory controller is configured to freeze a value of the first refresh timer when the memory device is in self refresh mode.

16. The integrated circuit as recited in claim 15, wherein the memory controller is configured to enable the first refresh timer in response to an exit from the self refresh mode.

17. The integrated circuit as recited in claim 16, wherein the memory controller is configured to adjust the first refresh timer in response to the exit to account for sources of error in measuring a refresh interval for the memory device.

18. The integrated circuit as recited in claim 15, wherein the memory controller is configured to inhibit generation of a refresh command in response to the exit from the self refresh mode until the first refresh timer expires.

19. A memory device comprising:
a first refresh timer; and
a control circuit configured generate self refresh commands for the memory device during self refresh mode dependent on the first refresh timer maintained by the control circuit, and wherein the control circuit is configured to ensure that an amount of time expiring in a refresh interval indicated by the first refresh timer at exit from the self refresh mode in the memory device is maintained, and wherein the control circuit is configured to trigger a next self refresh command after entry into self refresh mode and after a second amount of time from the entry, wherein a sum of the first amount of time and the second amount of time is approximately the refresh interval.

20. The memory device as recited in claim 19, wherein the control circuit is configured to adjust the first refresh timer in response to the entry to account for sources of error in measuring the refresh interval.
